(19) United States
(12) Patent Application Publication
(10) Pub. No.: US 2013/0042907 A1
(43) Pub. Date: Feb. 21, 2013

(54) SOLAR CELL DEVICE

(71) Applicants: Chang Ming-Nan, Hsinchu (TW); Liu Tsung-Hsien, Hsinchu (TW); Lee Shih-Chang, Hsinchu (TW)

(72) Inventors: Chang Ming-Nan, Hsinchu (TW); Liu Tsung-Hsien, Hsinchu (TW); Lee Shih-Chang, Hsinchu (TW)

(21) Appl. No.: 13/587,372

(22) Filed: Aug. 16, 2012

(30) Foreign Application Priority Data
Aug. 17, 2011 (TW) 100129530

(51) Int. Cl. H01L 31/0216; H01L 31/0725

(52) U.S. Cl. 136/255; 136/256

(57) ABSTRACT

Disclosed is a photovoltaic device comprising: a substrate; a III-V solar cell structure having one p-n junction on the substrate; a first semiconductor window layer on the III-V solar cell structure; a second semiconductor window layer on the first semiconductor window layer; an anti-reflective layer on the second semiconductor window layer; a contact layer disposed in the anti-reflective layer and on the second semiconductor window layer; and an electrode on the contact layer, wherein the second semiconductor window layer does not contain aluminum.

### TECHNICAL FIELD

The application relates to a solar cell device, and more particular to a solar cell device with an improved electrical performance.

### DESCRIPTION OF BACKGROUND ART

Due to the high oil price and environmental issues, the solar cells are highly valued. Among them, the concentrated photovoltaic is most potential to be developed. The concentrated photovoltaic mainly comprises a solar cell composed of III-V group material. In a condition when light is not concentrated, this type of solar cell has very high photoelectric conversion efficiency, and shows great potential to take the place of the conventional power sources.

Currently, an anti-reflective layer (Anti-Reflective Coating, ARC) is generally disposed directly on the window layer in most solar cells, as the structure shown in FIG. 1. This type of solar cell comprises a substrate 110; a III-V solar cell structure 120 comprising one p-n junction on the substrate 110; a window layer 130 on the solar cell structure 120; an anti-reflective layer 150 (comprising the first anti-reflective material layer 151 and the second anti-reflective material layer 152) on the window layer 130; a contact layer 160 in the anti-reflective layer 150 and on the window layer 130; and an electrode 170 on the contact layer 160.

### SUMMARY OF THE DISCLOSURE

Disclosed is a photovoltaic device comprising: a substrate; a III-V solar cell structure having one p-n junction on the substrate; a first semiconductor window layer on the III-V solar cell structure; a second semiconductor window layer on the first semiconductor window layer; an anti-reflective layer on the second semiconductor window layer; a contact layer disposed in the anti-reflective layer and on the second semiconductor window layer; and an electrode on the contact layer, wherein the second semiconductor window layer does not contain aluminum.

### BRIEF DESCRIPTION OF THE DRAWINGS

FIG. 1 illustrates a photovoltaic device known in the prior art which has an anti-reflective layer disposed directly on a window layer.

FIG. 2 illustrates the testing data of the electrical characteristics of the photovoltaic device shown in. FIG. 1.

FIG. 3 illustrates a photovoltaic device in accordance with one embodiment of the present application.

FIG. 3A illustrates the III-V material based solar cell structure which comprises one p-n junction solar cell structure in the photovoltaic device shown in FIG. 3.

FIG. 4 illustrates the testing data of the electrical characteristics of the photovoltaic device in accordance with one embodiment of the present application, wherein GaInP is adopted as the material of the second window layer.

FIG. 5A illustrates the testing data of the electrical characteristics of the photovoltaic device in accordance with one embodiment of the present application, wherein GaP is adopted as the material of the second window layer.

### DETAILED DESCRIPTION OF PREFERRED EMBODIMENTS

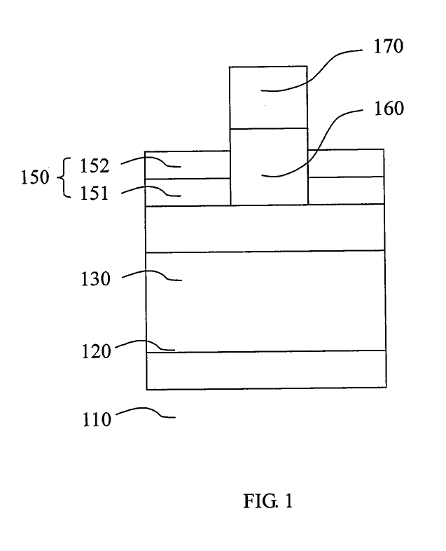

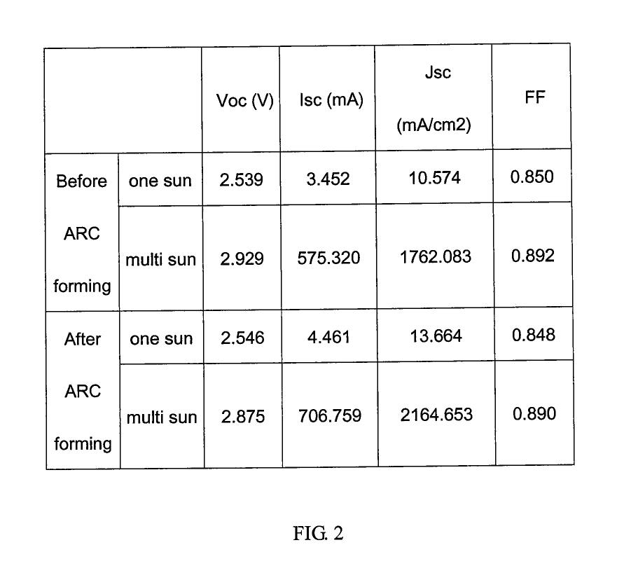

Generally speaking, the solar cell comprising the III-V group material has better photoelectric performance. When the electrical characteristics of a solar cell comprising the III-V material, such as the maximum output power density (Pmd) or conversion efficiency (η) is assessed, the open-circuit voltage (Voc), the short-circuit current density (Jsc), and the fill factor (FF) are particularly important. The electrical characteristics data of the solar cell in the FIG. 1 is shown in FIG. 2. As the data shows, this type of structure is likely to have a great drop of the open-circuit voltage (Voc) under the high light concentration (multi sun). According to the data, before forming the anti-reflective layer 150, the open-circuit voltage (Voc) is 2.929V, and after forming the anti-reflective layer 150, the open-circuit voltage (Voc) drops to 2.875V, i.e. 0.054V lower. The open-circuit voltage (Voc) in the high light concentration gets significantly worse. If the problem of declining of the open-circuit voltage (Voc) in the high light concentration is improved, the electrical characteristics of the device can be greatly improved.

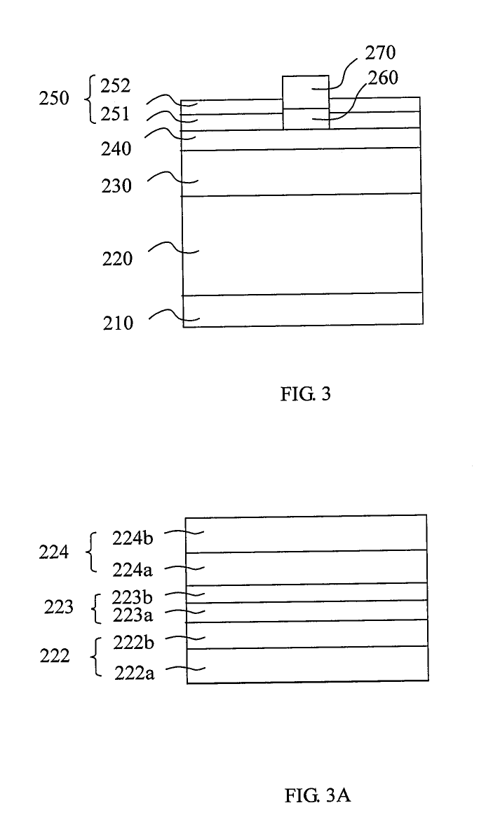

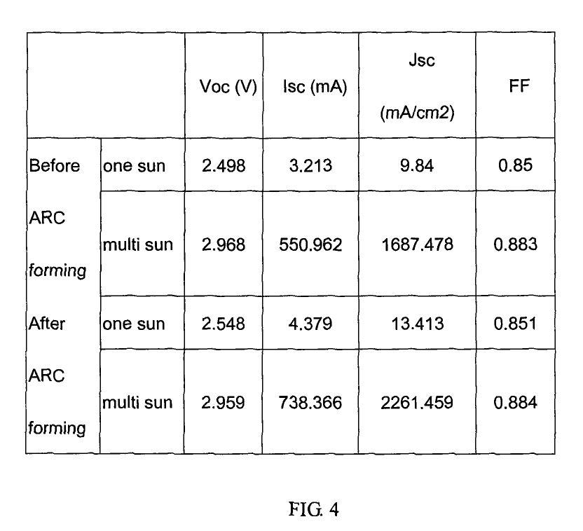

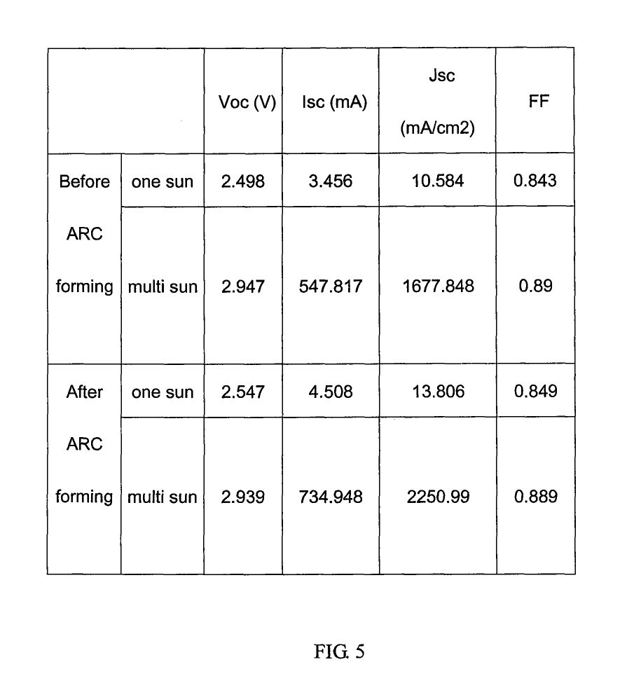

Please refer to the FIG. 3, which shows one of the embodiments of the solar cells of the application. First, a substrate 210 is provided; and subsequently, a III-V solar cell structure 220 comprising one p-n junction is formed on the substrate 210; a first window layer 230 is formed on the solar cell structure 220; a second window layer 240 is formed on the first window layer 230; an anti-reflective layer 250 is formed on the second window layer 240; a contact layer 260 is formed in the anti-reflective layer 250 and on the second window layer 240; and an electrode 270 is formed on the contact layer 260. The substrate 210 can be a Ge substrate or GaAs substrate. The III-V solar cell structure 220 comprising one p-n junction can be a single junction solar cell or a multi junction solar cell. In this embodiment, the solar cell structure 220 is illustrated by a dual junction solar cell structure, as shown in the FIG. 3A, which comprises a lower battery 222 close to the substrate 210 and a top battery 224 away from the substrate 210. The lower battery 222 and the top battery 224 are connected to each other with a tunnel junction structure 223 therebetween. The lower battery 222 comprises two layers of GaAs layers 222a, 222b with different polarity, and the top battery 224 comprises two layers of GaInP layers 224a, 224b with different polarity. The tunnel junction structure 223 is composed of two layers of AlGaAs layers 223a, 223b with different polarity. The tunnel junction structure 223 and the lower battery 222 (or the top battery 224) form diodes in anti-series connection electrically. In this embodiment, the GaAs layers 222a, 222b of the lower battery 222 are p-type and n-type, respectively. The GaInP layers 224a, 224b of the top battery 224 are p-type and n-type, respectively. And the AlGaAs layers 223a, 223b of the tunnel junction structure 223 are n-type and p-type, respectively. The material of the first window layer 230 may be AlGaAs or AlInP, and its thickness ranges from 100 Å to 700 Å. The material of the second window layer 240 is a semiconductor material which does not contain aluminum (Al), such as GaP or GaInP, and its thickness is less than 100 Å. The first window layer 230 and the second window layer 240 can be formed by MOCVD (Metal Organic Chemical Vapor Deposition) method. The anti-reflective layer 250 may comprise a first anti-reflective material layer 251 close to the second window layer 240, which in this embodiment is a titanium dioxide (TiO₂) layer with a thickness of from 200 Å to 800 Å, and a second anti-reflective material layer 252 away from the second window layer 240, which in this embodiment is an aluminum oxide (Al₂O₃) layer with a thickness of from 300 Å to 1000 Å. The titanium dioxide (TiO₂) layer of the first anti-reflective material layer 251 and the aluminum oxide (Al₂O₃) layer of the second anti-reflective material layer 252 can be formed by evaporation using the E-gun. The material of the contact layer 260 is a semiconductor material with a low energy band gap to facilitate the formation of ohmic contact between the contact layer 260 and the electrode 270, and the lattice constant of the material of the contact layer 260 is required to match that of the second window layer 240 to ensure the quality of the contact layer 260 when grown by MOCVD. The material of the contact layer 260 can be semiconductor materials such as GaAs and InGaAs. The material of the electrode 270 can be metal, for example, the material selected from the group of gold, silver, aluminum, copper, nickel, germanium, titanium, platinum, palladium, and chromium. For a solar cell of this structure, the electrical characteristics obtained in a testing are shown in FIG. 4 and FIG. 5, wherein FIG. 4 shows the data when GaInP is used for the second window layer 240, and FIG. 5 shows the data when GaP is used for the second window layer 240. As the data in FIG. 4 shows, before the deposition of the anti-reflective layer 250, the open-circuit voltage (Voc) in the high light concentration (multi sun) is 2.968V, and after the deposition of the anti-reflective layer 250, the open-circuit voltage (Voc) drops to 2.959V, by only 0.009V. In contrast with the structure in the FIG. 1 which has a declining value of 0.054V, the open-circuit voltage (Voc) of the structure in this embodiment in the high light concentration (multi sun) is significantly improved. And as the data in FIG. 5 shows, before the deposition of the anti-reflective layer 250, the open-circuit voltage (Voc) in the high light concentration (multi sun) is 2.947V, and after the deposition of the anti-reflective layer 250, the open-circuit voltage (Voc) drops to 2.939V, by only 0.008V. In contrast with the structure in the FIG. 1 which has a declining value of 0.054V, the open-circuit voltage (Voc) of the structure in this embodiment in the high light concentration (multi sun) is significantly improved. These results show that the structure in FIG. 3, where the second window layer 240 is formed on the first window layer 230, prevents the open-circuit voltage (Voc) of the device in the high light concentration from drastically dropping. In addition, the short-circuit current density (Jsc) is kept at a substantially same level, and the device has a better electrical characteristics. A calculation of the maximum output power density, wherein the maximum output power density (Pmd)=open-circuit voltage (Voc)×the short-circuit current density (Jsc)×the Fill Factor (FF), shows that for the structure in the FIG. 1 in the high light concentration (multi sun), before the deposition of the anti-reflective layer, the maximum output power density (Pmd)=2.929×1762.083×0.892=4606.373 (mW/cm²). Similarly, after the deposition of the anti-reflective layer, the maximum output power density (Pmd)=5540.643 (mW/cm²). The ratio of the maximum output power density (Pmd) after the deposition of the anti-reflective layer to the maximum output power density (Pmd) before the deposition of the anti-reflective layer is 1.203(=5540.643 (mW/cm²)/4606.373 (mW/cm²)). That is, the maximum output power density (Pmd) increases 20.3%. In contrast, a similar calculation is done based on the data in FIG. 4 and FIG. 5, and the maximum output power density (Pmd) increases 33.8% and 33.6% after the deposition of the anti-reflective layer, respectively. This result shows a great increase in comparison with the 20.3% for the structure shown in FIG. 1. The cause of this result is that the material of the second window layer 240 is a semiconductor material which does not contain aluminum (Al). For example, the materials such as GaP or GaInP in the embodiment of the present application are materials without aluminum (Al). It can prevent the aluminum (Al) element in AlGaAs or AlInP of the first window layer 230 from reacting with the TiO₂ layer of the anti-reflective layer 250 during the evaporation process of the anti-reflective layer 250 which comprises the TiO₂ layer and the Al₂O₃ layer by adding the second window layer 240 without aluminum (Al) on the first window layer 230. Otherwise the aluminum (Al) element in AlGaAs or AlInP of the first window layer 230 would react with the TiO₂ layer to oxidizing the aluminum (Al) element and cause low Voc. Accordingly, the damage to the first window layer 230 (AlGaAs or AlInP) by the evaporation process of the anti-reflective layer 250 is reduced, and the device is so protected to have a better efficiency. Based on this principle, it is understood that it is not necessary for the energy band gap of the second window layer 240 to be higher than the energy band gap of the first window layer 230. That is, the selection of the material for the second window layer 240 is not limited by the criterion of the energy band gap. A material of the second window layer 240 with an energy band gap greater than that of the first window layer 230 may be selected, and a material of the second window layer 240 with an energy band gap not greater than (i.e., less than or equal to) that of the first window layer 230 may also be selected. The thickness of the second window layer 240 should not be too thick, and is preferably lower than 200 Å, and the most preferably lower than 100 Å, so the incident light is not absorbed to harm the performance of the solar cell. In addition, although a lattice mismatch still occurs between a thinner second window layer 240 and the window layer 230 below, a thinner second window layer 240 is easier to have an elastic deformation to make its lattice constant consistent with that of the window layer 230 below. If the second window layer 240 is too thick, the second window layer 240 has a large stress and tends to revert to its original lattice constant, which causes lattice defects. So, a thinner second window layer 240 has a better tolerance to the lattice constant mismatch to the first window layer 230.

The above-mentioned embodiments are only examples to illustrate the theory of the present invention and its effect, rather than be used to limit the present invention. Other alternatives and modifications may be made by a person of ordinary skill in the art of the present application without escaping the spirit and scope of the application, and are within the scope of the present application.

What is claimed is:

1. A photovoltaic device, comprising:
a substrate;
a III-V solar cell structure having one p-n junction on the substrate;
a first semiconductor window layer on the III-V solar cell structure;
a second semiconductor window layer on the first semiconductor window layer;
an anti-reflective layer on the second semiconductor window layer;
a contact layer disposed in the anti-reflective layer and on the second semiconductor window layer; and
an electrode on the contact layer, wherein the second semiconductor window layer does not contain aluminum.

2. The photovoltaic device as claimed in claim 1, wherein the material of the first semiconductor window layer comprises AlGaAs or AlInP.

3. The photovoltaic device as claimed in claim 1, wherein the material of the second semiconductor window layer comprises GaP or GaInP.

4. The photovoltaic device as claimed in claim 1, wherein the thickness of the first semiconductor window layer is in a range from 100 Å to 700 Å, and/or the thickness of the second semiconductor window layer is less than 100 Å.

5. The photovoltaic device as claimed in claim 1, wherein the solar cell structure comprises a single junction solar cell or a multi-junction solar cell.

6. The photovoltaic device as claimed in claim 1, wherein the solar cell structure comprises a dual junction solar cell which comprises a lower battery comprising two layers of GaAs with different polarity close to the substrate and a top battery comprising two layers of GaInP with different polarity away from the substrate.

7. The photovoltaic device as claimed in claim 1, wherein the substrate comprises a Ge substrate or a GaAs substrate.

8. The photovoltaic device as claimed in claim 1, wherein the anti-reflective layer comprises a titanium dioxide (TiO₂) layer close to the second window layer and an aluminum oxide (Al₂O₃) layer away from the second window layer.

9. The photovoltaic device as claimed in claim 8, wherein the titanium dioxide (TiO₂) layer comprises a thickness of from 200 Å to 800 Å, and the aluminum oxide (Al₂O₃) layer comprises a thickness of from 300 Å to 1000 Å.

10. The photovoltaic device as claimed in claim 1, wherein an energy band gap of the second window layer is not greater than that of the first window layer.
